(19) United States
(12) Patent Application Publication
(10) Pub. No.: US 2006/0220242 A1
(43) Pub. Date: Oct. 5, 2006

(54) Method for producing flexible printed wiring board, and flexible printed wiring board

(75) Inventor: Hirokazu Kawamura, Ageo-shi (JP)

Correspondence Address: THE WEBB LAW FIRM, P.C., 700 KOPPERS BUILDING, 436 SEVENTH AVENUE, PITTSBURGH, PA, 15219, US

(73) Assignee: Mitsui Mining & Smelting Co., Ltd., Shinagawa-ku (JP)

(21) Appl. No.: 11/390,691

(22) Filed: Mar. 28, 2006

(30) Foreign Application Priority Data
Mar. 30, 2005 (JP) 2005-097369

(51) Int. Cl. H01L 23/48

(52) U.S. Cl. 257/737

(57) ABSTRACT

The present invention provides a method for producing a flexible printed wiring board which allows formation of a bump on a wire trace even in a high-density mounting process, and a flexible printed wiring board which realizes high-density mounting with high reliability. In the method for producing a flexible printed wiring board including an insulating layer and a wiring pattern on which a semiconductor chip is to be mounted, the pattern being formed of a conductor layer provided on at least one surface of the insulating layer, the method includes a first etching step including applying a photoresist onto a conductor layer and light-exposing the photoresist by the mediation of a first mask, followed by development, to thereby form a first resist pattern, and etching the conductor layer so as to penetrate the layer in the depth direction, to thereby form a first wiring pattern; and a second etching step including light-exposing the first resist pattern by the mediation of a second mask, followed by development, to thereby form a second resist pattern formed of a remaining portion of the first resist pattern, subsequently, leaving, as a thick portion, a portion of the first wiring pattern covered by the second resist pattern, and half-etching a portion other than the thick portion to an intermediate thickness of the conductor layer, to thereby form a second wiring pattern in the form of a thin portion having a thickness relatively smaller than that of the thick portion.

The entire disclosure of Japanese Patent Application No. 2005-97369 filed Mar. 30, 2005 is expressly incorporated by reference herein.

### BACKGROUND OF THE INVENTION

1. Field of the Invention

The present invention relates to a method for producing a flexible printed wiring board suitably employed as, for example, a COF (chip-on-carrier) film carrier tape or a COF flexible printed circuit (FPC), for mounting electronic devices such as ICs and LSIs thereon, and to a flexible printed wiring board. The term “COF film carrier tape” refers to a film substrate assuming the form of tape onto which electronic devices (chips) are to be mounted. The term “COF flexible printed wiring board” refers to a flexible printed wiring board-onto which electronic devices (chips) are to be mounted.

2. Description of the Related Art

Development of the electronics industry has been accompanied by sharp demand for printed-circuit boards for mounting electronic devices thereon, such as ICs (Integrated Circuits) and LSIs (Large-Scale Integrated circuits). Manufacturers have attempted to realize small-size, lightweight, and high-function electronic equipment, which has long been desired. To this end, manufacturers have recently come to employ a film carrier tape for mounting electronic devices thereon, such as a TAB (tape automated bonding) tape, a T-BGA (ball grid array), a TAB tape for an ASIC tape, or an FPC (flexible printed circuit). Use of such film carrier tapes has become of increasing importance, especially for manufacturers of personal computers, cellular phones, and other electronic equipment employing a liquid crystal display (LCD) that must have high resolution and flatness, as well as a narrow screen-frame area.

In addition, in order to attain higher-density mounting on a narrower space, unconnected IC chips have been mounted directly on a flexible printed wiring board. Such a product is called COF (chip-on-film).

Since the flexible printed wiring board serving as a substrate of COFs does not have a device hole, a laminate film obtained by laminating in advance a conductor layer and an insulating layer is employed as the flexible printed wiring board. When IC chips are mounted directly on the wiring pattern, positioning is performed on the basis of marks such as an inner lead and a positioning mark which are visible from the insulating layer, followed by joining gold bumps provided on a lead electrode of each IC chip and the wiring pattern; i.e., the inner lead, by means of a heating tool (see, for example, Japanese Patent No. 3350352, claims and paragraph [0005]). The joining is preformed through, for example, hot pressing making use of an Au—Sn eutectic alloy.

Meanwhile, Japanese Patent Application Laid-Open (kokai) No. 11-312857 (see, for example, claims) discloses an approach including provision of bumps on an inner lead instead of provision of gold bumps on an IC chip. Specifically, bumps are formed through half etching (i.e., etching the object to an intermediate point in the thickness direction), followed by forming a wiring pattern including the bumps. However, when this approach is employed, application of resist and a subsequent photolithographic step must be performed twice, making the process cumbersome, which is problematic.

Japanese Patent Application Laid-Open (kokai) No. 2003-218009 (see, for example, claims and Modes for Carrying Out the Invention) discloses a double etching method in which different etching patterns are formed through subjecting the resist pattern twice to an exposure/development step. However, when a pattern including bumps is formed through the above method, a groove between traces must be formed through etching twice in the second etching step, making the method unsuitable for micro-patterning.

Japanese Patent Application Laid-Open (kokai) No. 2004-328001 (see, for example, claims and Modes for Carrying Out the Invention) discloses a method in which a resist film adhering on a wiring pattern is subjected to an exposure/development step, to thereby form an opening in the film, and bumps are formed at the openings through copper plating.

However, when the above method is employed under high-density (e.g., 30 μm-pitch) wiring conditions, a trace top width is about 12 μm, as compared with a trace bottom width of 15 μm, and openings having a diameter of 10 μm are formed on the top surface of the trace. When bumps are formed through copper plating, plate failure and variation in bump height occur, resulting in problematic contact failure during joining of the bumps with IC chips. In addition, after development of the film, the formed bumps tend to assume the shape of a truncated cone having an inverted trapezoidal cross-section, resulting in stress concentration to the printed wiring board during joining with chips and pressing out the pattern, which is problematic. Another problem is that copper may be deposited also on a side surface of a trace during copper plating, leading to short circuit with an adjacent trace. When this method is employed, a sequential step of resist application, exposure, and development must be performed twice, which is also problematic.

### SUMMARY OF THE INVENTION

Under the aforementioned circumstances, an object of the present invention is to provide a method for producing a flexible printed wiring board which allows formation of a bump on a wire trace even in a high-density mounting process. Another object is to provide a flexible printed wiring board which realizes high-density mounting with high reliability.

Accordingly, in a first aspect of the present invention, there is provided a method for producing a flexible printed wiring board including an insulating layer and a wiring pattern on which a semiconductor chip is to be mounted, the pattern being formed of a conductor layer provided on at least one surface of the insulating layer, wherein the method comprises

a first etching step including
applying a photoresist onto a conductor layer and UV (Ultra Violet) light-exposing the photoresist by the mediation of a first mask, followed by development, to thereby form a first resist pattern, and
etching the conductor layer so as to penetrate the layer in the depth direction, to thereby form a first wiring pattern, and

a second etching step including
UV light-exposing the first resist pattern by the mediation of a second mask, followed by development, to thereby form a second resist pattern formed of a remaining portion of the first resist pattern,
subsequently, leaving, as a thick portion, a portion of the first wiring pattern covered by the second resist pattern, and
half-etching a portion other than the thick portion to an intermediate thickness of the conductor layer, to thereby form a second wiring pattern in the form of a thin portion having a thickness relatively smaller than that of the thick portion.

In the above method, the conductor layer is completely etched in the thickness direction in the first etching step, to thereby form a wiring pattern, and the resist pattern employed in the first etching step is light-exposed and developed again, followed by half-etching wire traces of the wiring pattern, to thereby form a thick portion on the wiring pattern. Therefore, the method is applicable to very high-density wiring patterns.

In the above method, the thick portion may be a bump formed on a wiring.

Thus, bumps can be formed with high positional accuracy on a high-density wiring pattern.

The production method may further include a step of forming a protrusion or a needle-like nodule on the bump.

Through formation of a soft nodule on the top surface of the bump, the wiring board and a device chip can be joined together at low contact resistance without use of an anisotropically conductive film (ACF).

In a second aspect of the present invention, there is provided a flexible printed wiring board comprising

an insulating layer,

a wiring pattern on which a semiconductor chip is to be mounted, the pattern being formed of a conductor layer provided on at least one surface of the insulating layer,

a bump to which a lead electrode of the semiconductor chip is connected, the bump being formed on a trace of at least one of an inner lead and an outer lead of the wiring pattern on which the semiconductor chip is to be mounted and being integrally formed with the wiring pattern,

wherein the lateral sides of the trace on which the bump has been formed are aligned flush with corresponding sides of the bump.

In the flexible printed wiring board, since the trace of the wiring has a bump having the same width, joining to an IC chip or a substrate surface can be attained with high alignmentally accuracy even in the case of high-density wiring.

The bump may be formed through half-etching the trace.

In the above case, the bump is formed through half-etching the patterned wiring. Therefore, the bump is not offset with respect to the trace, and can be applied to high-density wiring.

In the flexible printed wiring board, the conductor layer may be a copper layer, and the bump may have, on at least the top surface thereof, a tin plate layer or a gold-nickel base plating layer.

In the case where the Sn plate layer is provided, the bump can be bonded to an electrode of an IC chip, the electrode having an Au layer on an Al-vapor-deposited portion, through inner lead bonding based on formation of Sn—Au eutectic alloy. In the case where the gold-nickel base plate layer is provided, the bump can be bonded directly to an Al-vapor-deposited portion of an electrode of an IC chip through inner lead bonding based on formation of Al—Au eutectic alloy.

The bump may have, on a surface thereof, a protrusion or a needle-like nodule.

Through formation of a soft nodule on the top surface of the bump, the bump and a device chip can be joined together at low contact resistance without use of an anisotropically conductive film (ACF).

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1A is a schematic plan view of a flexible printed wiring board (for COF tape) according to Embodiment 1 of the present invention;

FIG. 1B is a schematic cross-sectional view of the flexible printed wiring board (for COF tape) according to Embodiment 1 of the present invention;

FIG. 2 is a perspective view of a bump of the flexible printed wiring board according to Embodiment 1 of the present invention;

FIGS. 3A to 3G schematically show a production steps for the flexible printed wiring board according to Embodiment 1 of the present invention; and

FIG. 4 is a schematic view showing a connection state between the flexible printed wiring board and a device substrate.

### DETAILED DESCRIPTION OF PREFERRED EMBODIMENTS

An embodiment of the method for producing a flexible printed wiring board according to the present invention will next be described. Needless to say, the embodiment should not be construed as limiting the invention thereto.

### Embodiment 1

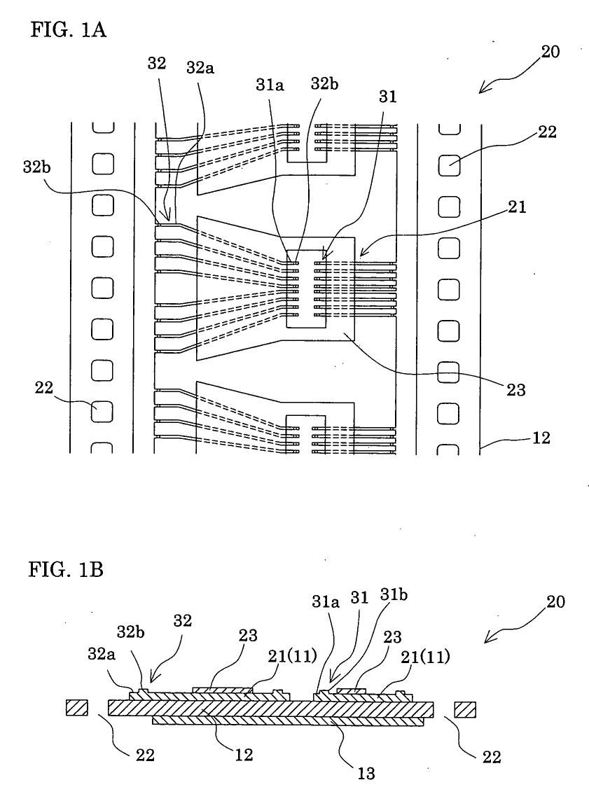

FIG. 1A is a schematic plan view of a flexible printed wiring board according to Embodiment 1 of the present invention, and FIG. 1B is a schematic cross-sectional view of the same. Although the flexible printed wiring board shown in FIG. 1 is for providing one device product, a flexible printed wiring board is continuously produced in the form of a long tape. Generally, electronic devices such as IC chips are mounted on the tape-form flexible wiring board while the tape is conveyed, and the tape is cut device by device. Alternatively, in some cases, mounting is performed after cutting of the tape. Embodiment 1 will be described while taking a tape-form flexible wiring board as an example.

Embodiment 1 will be described while taking a COF carrier tape as an example. Needless to say, the Embodiment is applicable to other FPCs for COF.

As shown in FIGS. 1A and 1B, the COF film carrier tape 20 according to the present embodiment is produced from a laminate film for producing a COF, the laminate film comprising a conductor layer 11 (copper layer) and an insulating layer 12 (polyimide film). The COF film carrier tape 20 has wiring patterns 21 obtained by patterning the conductor layer 11, and a pair of transversely spaced rows of sprocket holes 22 provided along opposite longitudinal edges; that is, the two rows of sprocket holes 22 are disposed such that one row extends along each of the opposite longitudinal edges of the wiring pattern 21. The wiring patterns 21 are provided on a surface of the insulating layer 12 continuously in the longitudinal direction of the film carrier tape.

The wiring pattern 21 has inner leads 31 on which devices such as IC chips are to be mounted, and outer leads 32 to be joined to substrates or other devices. In the vicinity of the end portion of each trace 31a of each inner lead 31 and of each trace 32a of each outer lead 32, a bump 31b and a bump 32b are formed, respectively, integrally with the corresponding trace.

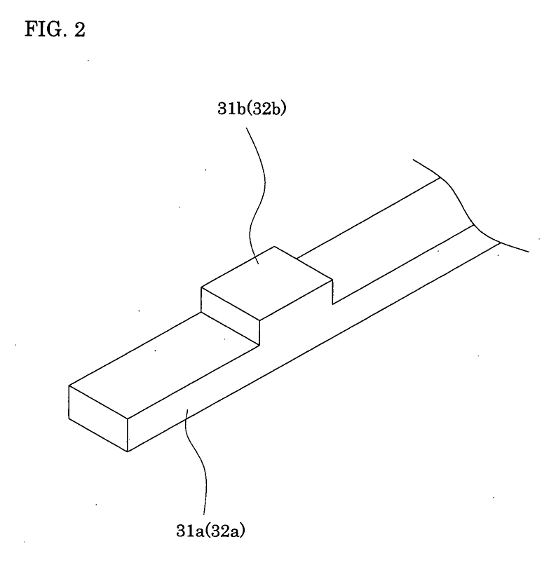

As shown in FIG. 2, the bump 31b or 32b has the same width as the trace 31a or 32a, and the lateral sides of the bump 31b or 32b and corresponding sides of the trace 31a or 32a on which the corresponding bump has been formed are aligned flush with each other. The bump and the trace were integrally formed through the etching process of the present invention described in detail later. Through employment of the etching process, the bump 31b or 32b having the same width as the trace 31a or 32a can be readily formed, even when the wiring has a high density (i.e., traces 31a and 32a are arranged at finer pitches). Thus, the inner leads 31 can be tightly joined to IC chips with high reliability. Without the bumps 32b, the outer leads 32 must be joined to devices such as LCD panels generally at high pressure by the mediation of an anisotropically conductive film (ACF) formed of an anisotropically conductive material. However, through provision of the bumps 32b, the outer leads 32 can be readily joined to the devices at low pressure.

Each wiring pattern 21 has, on a surface thereof, an insulating protective layer 23 which is formed by applying a solder resist coating solution through screen printing or attaching film thereto. On the backside of the insulating layer 12 and at least in an area where a bonding tool abuts during bonding of an electrode (such as an IC chip) and an inner lead, a releasing layer 13 is provided through application of a release agent or transfer of a transferable releasing layer. The releasing layer 13 may be provided on the entire backside of the insulating layer 12. The wiring patterns may be provided on both sides of the insulating layer 12 (such COF film carrier tape called “2-metal COF film carrier tape”). In this case, a releasing layer 13 is formed exclusively in an area where a heating tool is brought into contact with, through application of a release agent or transfer of a transferable releasing layer. Needless to say, provision of the releasing layer 13 is not obligatory.

Although the conductor layer 11 can be formed from a metal other than copper; e.g., aluminum, gold, or silver, a copper layer is generally employed. No particular limitation is imposed on the type of copper layer, and any type of copper layers, such as a copper layer formed through vapor deposition or plating, electrolyzed copper foil, or rolled copper foil, can be used. Generally, the conductor layer 11 has a thickness of 1 to 70 μm, preferably 5 to 35 μm.

The insulating layer 12 may be formed from, other than polyimide, a polymeric material such as polyester, polyamide, polyether-sulfone, or liquid crystalline polymer. Of these, an aromatic polyimide (all repeating units being aromatic) prepared by polymerizing pyromellitic dianhydride and 4,4′-diaminodiphenyl ether (e.g., Kapton EN, product of Du Pont-Toray Co., Ltd.) and biphenyltetracarboxylic dianhydride-p-phenylenediamine (PPD) polymer (e.g., Upilex S, product of Ube Industries, Ltd.) are preferred. The thickness of the insulating layer 12 generally falls within a range of 12.5 to 125 μm, preferably 12.5 to 75 μm, more preferably 12.5 to 50 μm.

The laminate film for producing a COF is produced by, for example, applying to a conductor layer 11 (copper foil) a polyimide precursor resin composition containing a polyimide precursor and varnish, to thereby form a coating layer; removing the solvent by drying; winding the coating layer; and heating the wound coating layer in an oxygen-purged curing furnace for imidization, to thereby form the insulating layer 12. However, no particular limitation is imposed on the method for producing the laminate film.

A releasing layer 13 can be formed from a silicone-based release agent containing a silazane compound or a release agent containing silica sol. Preferably, the releasing layer 13 is formed by providing a release agent on the insulating layer 12 through, for example, the application method, followed by heating to thereby attain strong bonding between the releasing layer 13 and the insulating layer 12. The thickness of the releasing layer 13 is controlled such that Si intensity, as determined by means of a wavelength dispersive X-ray fluorescence analyzer, falls within a range of 0.15 to 2.5 kcps, preferably about 0.3 to 1.0 kcps, more preferably about 0.5±0.1 kcps.

On the above-described COF film carrier tape of the present invention, chips or electronic devices are mounted. For example, while the tape or substrate is conveyed, semiconductor chips are mounted on the tape, or electronic devices are mounted on a print substrate, to thereby yield COF products. Since the insulating layer 12 including an area where the releasing layer 13 has been stacked has an optical transmittance of 50% or higher as measured at a wavelength of 600 nm, the image of the wiring patterns 21 (e.g., inner leads 31) can be recognized from the side of the insulating layer 12 by means of a CCD or a similar device. In addition, the wiring patterns of semiconductor chips and printed circuit boards to be mounted can be recognized. Thus, precise positioning of the wiring patterns with respect to the insulating layer 12 can be performed through image processing, thereby mounting electronic devices with high precision.

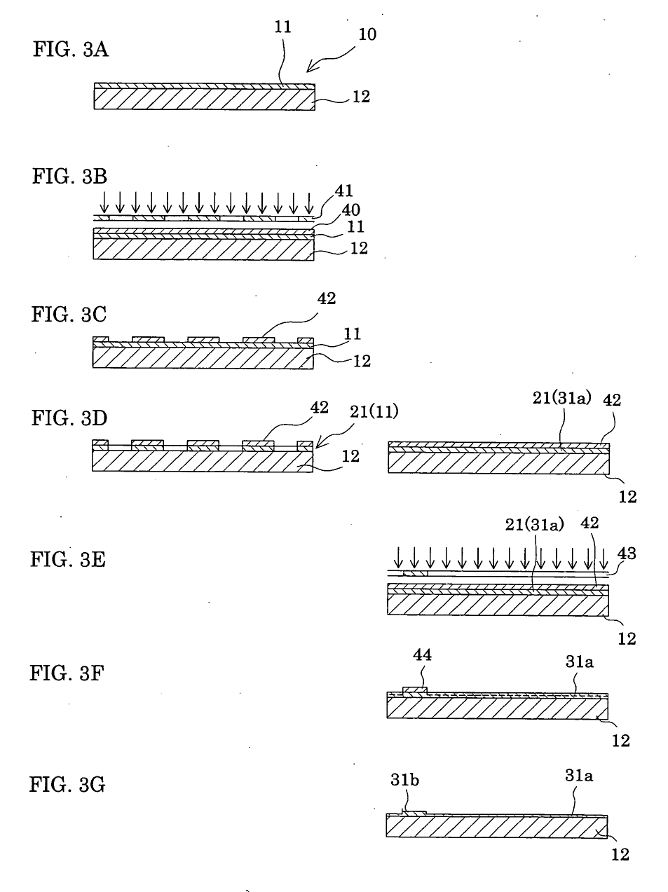

Next, one exemplary method of producing the aforementioned COF carrier tape will be described with reference to FIGS. 3A to 3G.

As shown in FIG. 3A, a laminate film 10 for producing a COF is provided. Although the procedure is not illustrated, the aforementioned sprocket holes 22 are formed, by punching or a similar method, through a conductor layer 11 and an insulating layer 12. The aforementioned sprocket holes 22 may be formed from the front side or the backside of the insulating layer 12. Then, as shown in FIG. 3B, a photoresist coating layer 40 is formed on a region of the conductor layer 11 for providing a wiring pattern 21, through a routine photolithographic method involving application of, for example, a positive type photoresist coating solution. Needless to say, a negative type photoresist may also be employed. After the insulating layer 12 is positioned by inserting positioning pins in the sprocket hole 22, the photoresist coating layer 40 is exposed and developed via a photomask 41 for patterning thereof, thereby forming a resist pattern 42 for providing a wiring pattern as shown in FIG. 3C. Subsequently, the conductor layer 11 is removed by dissolving with an etchant through the resist pattern 42 serving as a mask pattern, thereby forming a wiring pattern 21 as shown in FIG. 3D. The cross-section of a trace 31a of the wiring pattern 21 shown in the right column of FIG. 3D is viewed from a direction normal to that of the cross-section of the wiring pattern 21 shown in the left column of FIG. 3D.

Subsequently, as shown in FIG. 3E, the resist pattern 42 for providing a wiring pattern is UV light-exposed again through a photomask 43 having a mask pattern which exclusively covers the area where the aforementioned bump 31b is formed, followed by developing, to thereby leave a resist pattern 44 for forming a bump so as to cover the area where the aforementioned bump 31b is formed, as shown in FIG. 3F. While the resist pattern 42 is maintained, the trace 31a is half-etched in the thickness direction, to thereby integrally form the trace 31a having the bump 31b.

In the above process, the lateral sides of the bump 31b and corresponding sides of the trace 31a thereunder are aligned flush, since the bump and the trace have been integrally formed in the first etching step. The width of the bump 31b is virtually the same as that of the trace 31a. The bump 32b can be formed in a similar manner.

The thus-formed wiring pattern 21 is plated (e.g., plated with tin) in accordance with needs. Subsequently, a releasing layer 13 is formed, through the application method, on the surface of the insulating layer 12 opposite the side of the wiring pattern 21 and at least in an area where bonding of an electrode (such as an IC chip) and an inner lead is performed. Although the applied releasing layer 13 may be simply dried, heating of the layer is preferred, for enhancing a releasing effect; i.e., for preventing melt adhesion the insulating layer to a heating tool. Exemplary conditions under which the heating is performed are, but are not limited to, at 50 to 200° C. for one minute to 120 minutes, preferably 100 to 200° C. for 30 minutes to 120 minutes. The heating process may be performed simultaneously with curing solder resist.

Subsequently, an insulating protective layer 23 is formed through, for example, screen printing. The inner leads 31 and the outer leads 32, which are not covered with the insulating protective layer 23, are plated with a metal in accordance with needs. No particular limitation is imposed on the material of the metal plating layer, and tin plating, tin alloy plating, nickel plating, gold plating, gold alloy plating, or Pb-free solder plating such as Sn—Bi may appropriately be performed in accordance with the purpose of use.

The aforementioned embodiment has been described taking as an example a film carrier tape 20 for mounting electronic parts, the carrier tape having a single row of carrier patterns including wiring patterns 21 and sprocket holes 22. However, the present invention is not limited to these embodiments, and a film carrier tape for mounting electronic parts which film has a plurality of rows of carrier patterns also falls within the scope of the invention.

The above embodiment of the invention is directed to a film carrier tape for mounting electronic parts which film serves as a COF film carrier tape. However, other films carrier tape for mounting electronic parts; e.g., TAB, CSP, BGA, μ-BGA, FPC, and ASIC tapes also fall within the scope of the present invention, and no particular limitation is imposed on the structure and other factors of the film carrier tapes.

### EXAMPLES

### Example 1

A laminate film (Espanex M, product of Nippon Steel Chemical Co., Ltd.) in which copper foil (thickness: 12 μm) is laminated on polyimide film (thickness: 40 μm) was provided. The copper foil of the laminate film was completely coated with a positive-type photoresist liquid (FR 200, product of Rohm & Haas Co.) having a viscosity of 30 cPs was applied to a thickness of 4 to 5 μm by means of a roll coater. After drying, the photoresist was irradiated with a UV ray (320 mJ/cm²) through a glass photomask having a predetermined wire circuit pattern (in Example 1, including 720 straight traces having a width of 35 μm arranged at a pitch of 50 μm and serving as outer leads).

The thus-exposed resist was developed, to thereby form a photoresist pattern. The pattern was continuously etched through spraying thereto a solution of CuCl₂+HCl+H₂O₂ at 1.2 kg/cm². After completion of etching, the etched pattern was sequentially washed with hydrochloric acid and water, to thereby form a wiring pattern including outer leads. At this stage, the resist pattern was left on the wiring pattern.

The resist pattern was light-exposed again through a strip-form mask pattern covering the areas where bumps are provided on the outer leads. The exposure dose was controlled to 450 mJ/cm². After development of the resist pattern, half-etching was performed with the same etchant as employed in the above etching step, to thereby thin the portions not covered with the resist pattern. Thus, outer leads in which each trace has a thickness of 4 μm and each bump (protruded thick portion) has a thickness of 8 μm were formed. The top surface of each bump has a surface area of 21 μm×30 μm.

Each of the thus-formed bumps had virtually the same width as that of the traces. The lateral sides of each bump and corresponding sides of each trace are aligned flush, although the two sides were slightly slanted. The bump and the trace were not offset from each other in terms of the width direction, and no swelling was observed.

The top surface of each bump was covered with tin through electroless plating. Thus, a flexible printed wiring board including outer leads having bumps was produced. Since the flexible printed wiring board included outer leads having bumps, devices such as LCD substrates can be joined to the wiring board at comparatively low pressure by the mediation of an ACF or a similar material.

### Example 2

In Example 2, an exemplary case where protrusions or needle-like nodules were formed on a bump in order to enhance joining performance of the wiring board to devices such as LCD substrates.

In Example 2, a laminate film (Espanex M, product of Nippon Steel Chemical Co., Ltd.) in which copper foil (thickness: 15 μm) is laminated on polyimide film (thickness: 40 μm) was subjected to etching in a manner similar to that employed in Example 1, to thereby form bumps. Since the procedure employed in Example 2 until formation of bumps through etching was the same as employed in Example 1, detailed descriptions thereof are omitted.

After completion of etching, a solder resist ink was applied, through printing, onto the portions of the laminate film except the inner leads and the outer leads.

The film was subjected to plating in a plating bath prepared from a copper sulfate solution (Cu: 8 g/L, sulfuric acid: 100 g/L) and β-naphthoquinoline (50 ppm) at 30° C. and at a Dk of 3 A/dm² for 15 seconds. Subsequently, under normal deposition conditions (at 1 A/dm²), copper clad plating was effected, to thereby securely fix nodules onto the conductor surfaces of the outer leads and the inner leads. Subsequently, the film was further subjected to plating steps (nickel (Ni) 0.35 μm and gold 0.35 μm), to thereby form nodules having a height of 10 μm, which were sufficiently bonded to the copper conductor. The Ni plating was performed by use of an Ni sulfamate bath under the conditions of 55° C., 1.3 A/dm², and 80 seconds, and the Au plating was performed by use of a potassium cyanoaurate under the conditions of 65° C., 0.4 A/dm², and 90 seconds.

The thus-produced COF had a width of 48 mm. In the COF, the outer lead pitch was 120 μm, and the trace width was 44 μm. The bump height (except the nodules) was 8 μm, and the bump top surface had a surface area of 28 μm×42 μm.

Since the thus-formed COF has bumps having nodules thereon, joining of the COF to devices such as LCD panels can be realized with high positional accuracy, by the mediation of a non-conductive paste (NCP) or a non-conductive film (NCF) instead of an anisotropically conductive film (ACF). In other words, when no nodules are formed on the top surface of a bump, the bump has a hard surface which is to be in contact with devices. Thus, when a COF having such bumps is joined to the devices by use of an NCP or an NCF, the joining state lacks reliability when the joined product is subjected to temperature cycles. In contrast, when nodules or protrusions, having softness, are provided on the top surface of a bump, joining of the COF to devices can be realized by the mediation of an NCP or an NCF instead of a conventionally employed ACF. Thus, joining can be performed at low contact resistance.

### Other Examples

In the aforementioned Examples 1 and 2, one bump was provided on one trace. However, alternatively, a plurality of bumps may be provided on an outer lead trace of a wiring board, in a longitudinal direction of the trace, which is joined to devices such as LCD substrates. In this case, reliability of connection is enhanced.

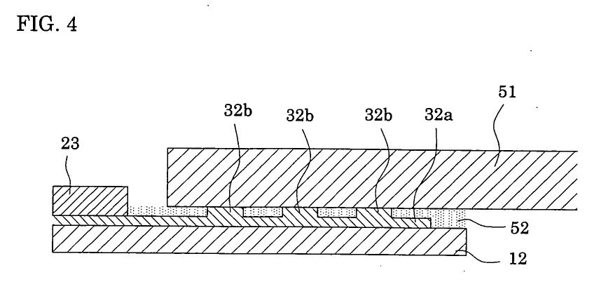

FIG. 4 shows an exemplary case where a plurality of bumps are provided. In FIG. 4, a flexible printed wiring board is joined to a substrate 51 of a device such as an LCD. In this case, a trace 32a is provided with three bumps 32b in the longitudinal direction. As illustrated in FIG. 4, portions between the bumps 32b represent connection material 52 such as an NCP or an NCF. Needless to say, connection may be performed by the mediation of an anisotropically conductive material (ACF).

According to method of the present invention for producing a flexible printed wiring board, a thick conductor portion can be formed on a high-density wiring pattern with high positional accuracy, through a comparatively simple etching process. Thus, a flexible printed wiring board having bumps formed on a high-density wiring pattern with high positional accuracy can be produced.

Since the flexible printed wiring board of the present invention has bumps each having the same width as a trace and formed on wiring traces with high positional accuracy, the wiring board is applicable to a high-density wiring pattern, and attains joining to IC chips and other devices with high positional accuracy.

What is claimed is:

1. A method for producing a flexible printed wiring board including an insulating layer and a wiring pattern on which a semiconductor chip is to be mounted, the pattern being formed of a conductor layer provided on at least one surface of the insulating layer, wherein the method comprises
a first etching step including
applying a photoresist onto a conductor layer and light-exposing the photoresist by the mediation of a first mask, followed by development, to thereby form a first resist pattern, and
etching the conductor layer so as to penetrate the layer in the depth direction, to thereby form a first wiring pattern, and
a second etching step including
light-exposing the first resist pattern by the mediation of a second mask, followed by development, to thereby form a second resist pattern formed of a remaining portion of the first resist pattern,
subsequently, leaving, as a thick portion, a portion of the first wiring pattern covered by the second resist pattern, and
half-etching a portion other than the thick portion to an intermediate thickness of the conductor layer, to thereby form a second wiring pattern in the form of a thin portion having a thickness relatively smaller than that of the thick portion.

2. A method for producing a flexible printed wiring board according to claim 1, wherein the thick portion is a bump formed on a wiring.

3. A method for producing a flexible printed wiring board according to claim 2, which further comprises a step of forming a protrusion or a needle-like nodule on the bump.

4. A flexible printed wiring board comprising
an insulating layer,
a wiring pattern on which a semiconductor chip is to be mounted, the pattern being formed of a conductor layer provided on at least one surface of the insulating layer,
a bump to which a lead electrode of the semiconductor chip is connected, the bump being formed on a trace of at least one of an inner lead and an outer lead of the wiring pattern on which the semiconductor chip is to be mounted and being integrally formed with the wiring pattern,
wherein the lateral sides of the trace on which the bump has been formed are aligned flush with corresponding sides of the bump.

5. A flexible printed wiring board according to claim 4, wherein the bump is formed through half-etching the trace.

6. A flexible printed wiring board according to claim 4, wherein the conductor layer is a copper layer, and the bump has, on at least the top surface thereof, a tin plate layer or a gold-nickel base plating layer.

7. A flexible printed wiring board according to claim 5, wherein the conductor layer is a copper layer, and the bump has, on at least the top surface thereof, a tin plate layer or a gold-nickel base plating layer.

8. A flexible printed wiring board according to claim 4, wherein the bump has a protrusion or a needle-like nodule on a surface thereof.

9. A flexible printed wiring board according to claim 5, wherein the bump has a protrusion or a needle-like nodule on a surface thereof.

10. A flexible printed wiring board according to claim 6, wherein the bump has a protrusion or a needle-like nodule on a surface thereof.

11. A flexible printed wiring board according to claim 7, wherein the bump has a protrusion or a needle-like nodule on a surface thereof.
